(19) United States
(12) Patent Application Publication
(10) Pub. No.: US 2013/0154058 A1
(43) Pub. Date: Jun. 20, 2013

(54) HIGH SURFACE AREA FILLER FOR USE IN CONFORMAL COATING COMPOSITIONS

(71) Applicants: Dylan J. Boday, Tucson, AZ (US); Joseph Kuczynski, Rochester, MN (US); Timothy J. Tofil, Rochester, MN (US)

(72) Inventors: Dylan J. Boday, Tucson, AZ (US); Joseph Kuczynski, Rochester, MN (US); Timothy J. Tofil, Rochester, MN (US)

(73) Assignee: International Business Machines Corporation, Armonk, NY (US)

(21) Appl. No.: 13/327,971

(22) Filed: Dec. 16, 2011

(51) Int. Cl. C07F 9/50; C09D 7/12; H01L 27/02

(52) U.S. Cl. 257/536; 106/287.14; 556/405

(57) ABSTRACT

A high surface area filler, a conformal coating composition, and an apparatus. The high surface area filler comprises an amorphous silicon dioxide powder and a phosphine compound bonded to the amorphous silicon dioxide powder. The conformal coating composition comprises a conformal coating and the high surface area filler. The apparatus includes an electronic component mounted on a substrate and metal conductors electrically connecting the electronic component. The conformal coating composition overlies the metal conductors and comprises a conformal coating and the high surface area filler. Accordingly, the conformal coating composition is able to protect the metal conductors from corrosion caused by sulfur components (e.g., elemental sulfur, hydrogen sulfide, and/or sulfur oxides) in the air.

### BACKGROUND

The present invention relates in general to the field of electronic hardware. More particularly, the present invention relates to a high surface area filler for use in conformal coating compositions to provide corrosion protection for metal conductors in electronic hardware.

Electronic components, such as microprocessors and integrated circuits, are generally packaged using electronic packages (i.e., modules) that include a module substrate to which one or more electronic component(s) is/are electronically connected. A single-chip module (SCM) contains a single electronic component such as a central processor unit (CPU), memory, application-specific integrated circuit (ASIC) or other integrated circuit. A multi-chip module (MCM), on the other hand, contains two or more such electronic components.

Generally, each of these electronic components takes the form of a flip-chip, which is a semiconductor chip or die having an array of spaced-apart terminals or pads on its base to provide base-down mounting of the flip-chip to the module substrate. The module substrate is typically a ceramic carrier or other conductor-carrying substrate.

Controlled collapse chip connection (C4) solder joints (also referred to as “solder bumps”) are typically used to electrically connect the terminals or pads on the base of the flip-chip with corresponding terminals or pads on the module substrate. C4 solder joints are disposed on the base of the flip-chip in an array of minute solder balls (e.g., on the order of 100 μm diameter and 200 μm pitch). The solder balls, which are typically lead (Pb)-containing solder but may be lead-free solder (e.g., Sn—Ag—Cu solder), are reflowed to join (i.e., electrically and mechanically) the terminals or pads on the base of the flip-chip with corresponding terminals or pads on the module substrate.

Corrosion caused by sulfur components (e.g., elemental sulfur, hydrogen sulfide, and/or sulfur oxides) in the air is especially severe when one or more of the metal conductors that electrically connect an electronic component is/are a silver-containing metal. For example, each of the gate resistors of a resistor network array typically utilizes a silver layer at each of the gate resistor's terminations. Gate resistors are also referred to as “chip resistors” or “silver chip resistors”. Sulfur components in the air will react with the silver layer in the gate resistor to form silver sulfide. This silver sulfide formation often causes the gate resistor to fail, i.e., the formation of silver sulfide, which is electrically non-conductive, produces an electrical open at one or more of the gate resistor's terminations.

The use of silver as an electrical conductor for electrically connecting electronic components is increasing because silver has the highest electrical conductivity of all metals, even higher than copper. In addition, the concentration of sulfur components in the air is unfortunately increasing as well. Hence, the problem of corrosion caused by sulfur components in the air is expected to grow with the increased use of silver as an electrical conductor for electrically connecting electronic components and the increased concentration of sulfur components in the air.

### SUMMARY

Aspects of an embodiment of the present invention disclose a high surface area filler, a conformal coating composition, and an apparatus. The high surface area filler comprises an amorphous silicon dioxide powder and a phosphine compound bonded to the amorphous silicon dioxide powder. The conformal coating composition comprises a conformal coating and the high surface area filler. The apparatus includes an electronic component mounted on a substrate and metal conductors electrically connecting the electronic component. The conformal coating composition overlies the metal conductors and comprises a conformal coating and the high surface area filler. Accordingly, the conformal coating composition is able to protect the metal conductors from corrosion caused by sulfur components (e.g., elemental sulfur, hydrogen sulfide, and/or sulfur oxides) in the air.

### BRIEF DESCRIPTION OF THE SEVERAL VIEWS OF THE DRAWINGS

FIG. 1 is an exploded view of a gate resistor of a resistor network array that utilizes a conformal coating composition, containing a high surface area filler, to protect metal conductors in accordance with a preferred embodiment of the present invention.

FIG. 2 is a sectional view of the gate resistor shown in FIG. 1, but which is shown mounted on a printed circuit board.

FIG. 3 is a top view of a resistor network array mounted on a printed circuit board that utilizes a conformal coating composition, containing a high surface area filler, to protect metal conductors in accordance with a preferred embodiment of the present invention.

### DETAILED DESCRIPTION

In accordance with a preferred embodiment of the present invention, an apparatus includes an electronic component mounted on a substrate and metal conductors electrically connecting the electronic component. A conformal coating composition overlies the metal conductors and comprises a conformal coating and a high surface area filler, wherein the high surface area filler comprises an amorphous silicon dioxide powder and a phosphine compound covalently bonded to the amorphous silicon dioxide powder. Accordingly, the conformal coating composition is able to protect the metal conductors from corrosion caused by sulfur components (e.g., elemental sulfur, hydrogen sulfide, and/or sulfur oxides) in the air.

The phosphine compound covalently bonded to the amorphous silicon dioxide powder reacts with any corrosion inducing sulfur component in the air and prevents the sulfur component from reacting with the underlying metal conductors. Using the high surface area filler significantly increases the number of reactive sites for reacting with sulfur components. Additionally, as this is a filler, it can be added to most conventional conformal coatings, thus improving a conformal coating's ability to provide corrosion protection.

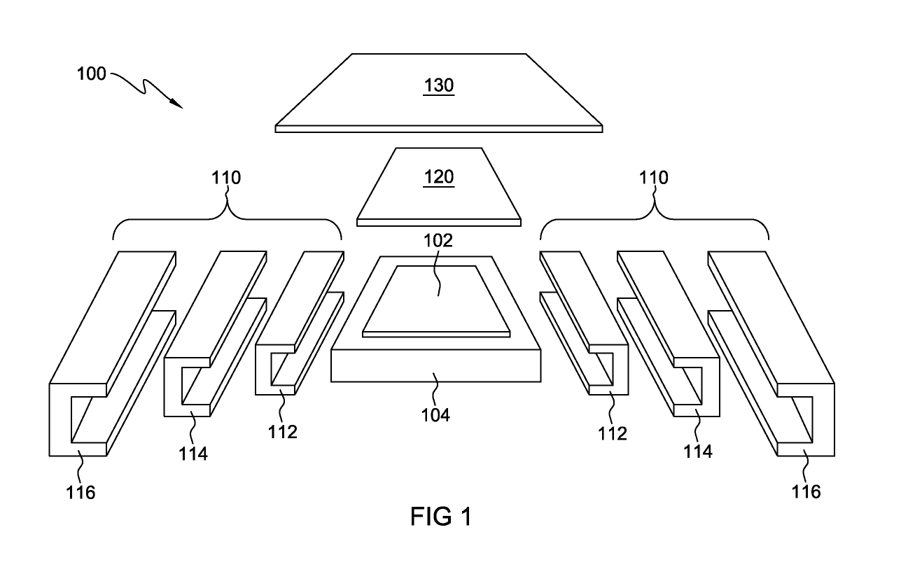

An embodiment of the invention is described herein in the context of protecting metal conductors of an exemplary gate resistor in a resistor network array from corrosion caused by sulfur components in the air. One skilled in the art will appreciate, however, that the present invention can also apply to protecting metal conductors of gate resistors and resistor network arrays having configurations differing from the gate resistor and resistor network array shown in FIGS. 1-3 and to protecting metal conductors of other electronic components, and, more generally, to protecting a metal surface of any product. For example, the present invention can be used to protect controlled collapse chip connection (C4) solder joints that electrically connect terminals or pads on the base of a flip-chip with corresponding terminals or pads on a module substrate.

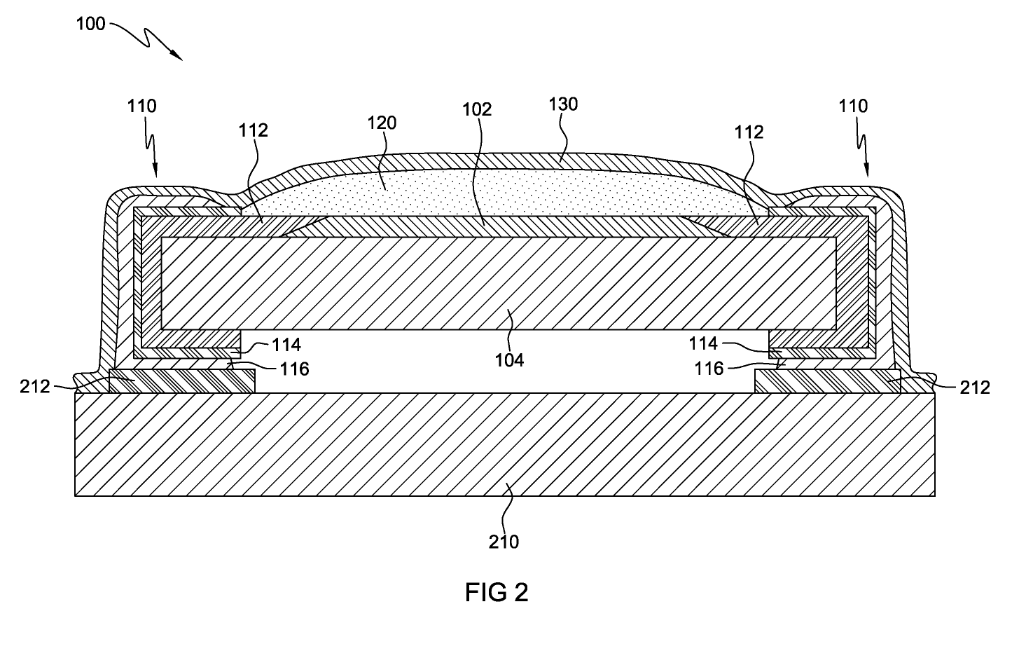

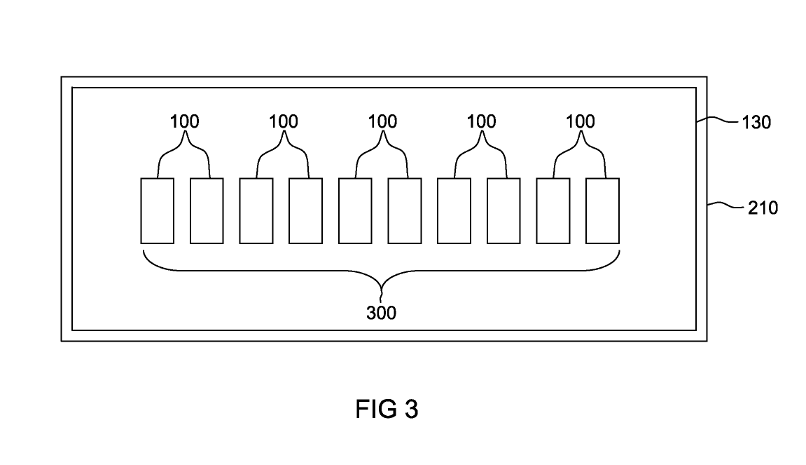

Referring now to FIG. 1, there is depicted, in an exploded view, a gate resistor 100 of a resistor network array (shown in FIG. 3) that utilizes a conformal coating composition 130, which according to a preferred embodiment of the present invention, provides corrosion protection for metal conductors. FIG. 2 is a sectional view of the gate resistor 100 shown in FIG. 3, but which is shown mounted on a printed circuit board 210. FIG. 3 is a top view of a resistor network array 300 that utilizes the conformal coating composition 130 shown in FIGS. 1 and 2.

As shown in FIGS. 1 and 2, a resistor element 102 is mounted to a substrate 104, such as a ceramic substrate. The gate resistor 100 includes two termination structures 110, each typically comprising an inner Ag (silver) layer 112, a protective Ni (nickel) barrier layer 114, and an outer solder termination layer 116. Each of the termination structures 110 of the gate resistor 100 is also referred to herein as a “metal conductor”.

Typically, for corrosion protection, each gate resistor in a resistor network array is coated with a conventional protective coating, such as a glass over coat 120.

The gate resistors in a resistor network array are typically soldered to a printed circuit board by SMT (surface mounting technology) processes. As best seen in FIG. 2, the termination structures 110 of each gate resistor 100 in the resistor network array 300 (shown in FIG. 3) are soldered to corresponding terminals or pads 212 on the printed circuit board 210. For example, the outer solder termination layer 116 of the termination structures 110 of each gate resistor 100 may be reflowed to join (i.e., electrically and mechanically) the termination structures 110 on the base of the gate resistor 100 with the corresponding terminals or pads 212 on the printed circuit board 210.

As best seen in FIG. 3, in accordance with a preferred embodiment of the present invention, the conformal coating composition 130 covers essentially the entire printed circuit board 210, encapsulating each of the gate resistors 100 of the resistor network array 300 (as well as any other discrete electronic component(s) mounted on the board 210). Hence, the conformal coating composition 130 overlies the metal conductors 110 of the gate resistor 100 to provide corrosion protection, i.e., the conformal coating composition 130 protects the metal conductors 110 of the gate resistor 100 from corrosion caused by sulfur components (e.g., elemental sulfur, hydrogen sulfide, and/or sulfur oxides) in the air.

Alternatively, the conformal coating composition 130 may cover only one or more specific areas of the printed circuit board 210 that is/are susceptible to corrosion caused by sulfur components in the air (e.g., the area of the printed circuit board 210 encompassing the resistor network array 300).

The conformal coating composition 130 contains a high surface area filler that has sulfur gettering functionality which can significantly extend the product life when the gate resistor 100 (or other electronic component) is to be used in a corrosive gas environment. This benefit of the present invention is achieved without affecting the operation of the gate resistor 100 (or other electronic component).

Advantageously, existing deposition processes may be used for applying the conformal coating composition 130 to the printed circuit board 210, and thereby encapsulate the resistor network array 300 and other discrete electronic component(s) mounted on the printed circuit board 210. The present invention may be implemented in any currently used conformal coating process utilized in the preparation of electronic components. Numerous processes conformally coat components.

For example, conformal coating composition 130 may be applied onto the printed circuit board 210 to encapsulate the resistor network array 300 in an at least partially uncured state by dipping, spraying, spin-coating, casting, brushing, rolling, syringe, or any other suitable deposition process. Then, the conformal coating composition 130 is cured. Generally, the process used to cure will vary based on the particular type of conformal coating used in the conformal coating composition.

Moreover, one skilled in the art will appreciate that the present invention is not limited to use in the preparation of electronic components. Indeed, the present invention may be implemented in any currently used conformal coating process utilized in the preparation of any product (e.g., painting the metal surfaces of automobiles, appliances, road signs, etc.).

The conformal coating composition 130 is composed of a conformal coating, and a high surface area filler, wherein the high surface area filler comprises an amorphous silicon dioxide powder and a phosphine compound covalently bonded to the amorphous silicon dioxide powder. Conformal coating composition 130 may be prepared by mixing the conformal coating and high surface area filler in a dispersion mixer. The concentration of the high surface area filler in the conformal coating composition 130, based on the total weight of the conformal coating and the high surface area filler in the conformal coating composition 130, may range from 0.01-55 wt %, preferably 10-40 wt % and most preferably 15-30 wt %.

The conformal coating in conformal coating composition 130 may be any commercially available polymer conformal coating. Polymer conformal coatings typically fall into one of several generic classes: silicones, epoxies, acrylates, or other organic materials. Hence, the polymer in the polymer conformal coating may be, for example, one or more silicon-based polymers, one or more epoxy-based polymers, one or more acrylate-based polymers, and/or one or more other organic materials; and combinations thereof.

The high surface area filler in conformal coating composition 130 comprises an amorphous silicon dioxide powder and a phosphine compound covalently bonded to the amorphous silicon dioxide powder. The high surface area filler may be prepared by reacting an amorphous silicon dioxide powder and a phosphine compound under acidic conditions in the presence of ethanol.

The amorphous silicon dioxide powder (SiO₂) may be a commercially available amorphous SiO₂ powder with a surface area in a range of 50 sq. m/g to 600 sq. m/g, preferably 150 sq. m/g to 250 sq. m/g.

The phosphine compound covalently bonded to the amorphous silicon dioxide powder may be one or more alkyl phosphines and/or one or more aryl phosphines; and combinations thereof. More particularly, the phosphine compound may be one or more substituted or unsubstituted butyl phosphines and one or more substituted or unsubstituted phenyl phosphines; and combinations thereof. For example, the phosphine compound may be a substituted phenyl phosphine of Formula (1):

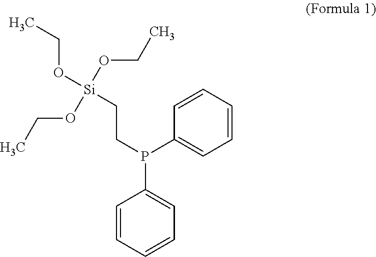 [SMILES: CCO[Si](CCP(c1ccccc1)c1ccccc1)(OCC)OCC]

### 2-(Diphenylphosphino)Ethyltriethoxysilane

It will be appreciated by those skilled in the art that, in accordance with a preferred embodiment of the present invention, the intent is to covalently bind a phosphine-functional group to the amorphous silicon dioxide powder to provide the sulfur-getting feature of the high surface area filler. As such, numerous phosphine derivatives or phosphine oxide derivatives can be envisaged that will accomplish the intended task.

The gettering functionality of the phosphine compound binds and traps the target corrosive species (i.e., sulfur components in the air). Binding this corrosive species prevents the diffusion of the corrosive species to the underlying metallurgy. This eliminates the possibility of the corrosive species reaching the underlying metallurgical surfaces of the electronic component, and thus prevents corrosion of those metallurgical surfaces.

### Example

The following example is intended to illustrate the invention to those skilled in the art and should not be interpreted as limiting the scope of the invention set forth in the claims. This example establishes the effectiveness of conformal coating compositions, containing a high surface area filler, at extending the time to corrosion failure of silver containing thick film resistors in a sulfur environment.

### High Surface Area Filler Preparation

The high surface area filler was prepared as follows. The high surface area filler was prepared by silylating an amorphous silicon dioxide powder with a phosphine compound under acidic conditions in the presence of ethanol. First, 1.0 g of amorphous silicon dioxide powder with a surface area of 200 sq. m/g was added to a 30 mL plastic bottle. To this bottle, a solution containing 15 mL of ethanol, 1 N acetic acid solution (0.1 g, 0.1 mL) and 2-(Diphenylphosphino)ethyltriethoxysilane (0.3 g, 0.79 mmol) was added followed by a stir bar. The bottle was sealed and placed onto a magnetic stirrer. The reaction was carried out at room temperature for 24 hours. The resulting high surface area filler was then purified by centrifugation at 6000 rpm at 25° C. The solution was decanted off of the high surface area filler and then redispersed in ethanol by sonication. This process was repeated 3 more times. The above reaction is illustrated generally in Scheme (1).

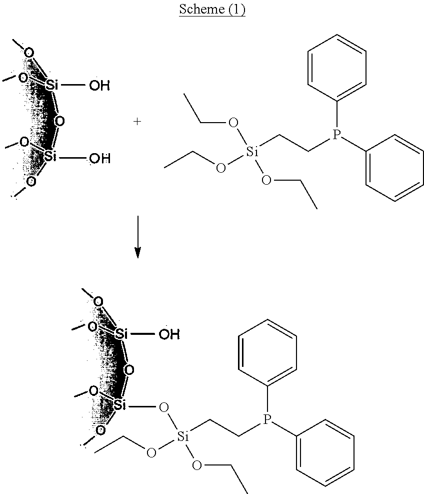 [SMILES: CCO[Si](CCP(c1ccccc1)c1ccccc1)(OCC)OCC ; CCO[Si](O)(CCP(c1ccccc1)c1ccccc1)OCC]

### Conformal Coating Composition Preparation

The conformal coating compositions were prepared as follows. To a commercially available RTV (Room Temperature Vulcanizing) conformal coating, mortar and pestle ground high surface area filler was added. This composition was then mixed using a VMA-Getzmann Dispermat® high speed dispersion mixer. Concentrations of the high surface area filler in the prepared compositions range from 10-25 wt % based on the total weight of the conformal coating and the high surface area filler in the composition. After being mixed, the conformal coating compositions were permitted to degas entrained air at ambient temperature for 10 minutes prior to being applied to the resistor arrays.

### Conformal Coating Composition Testing

To test the effectiveness of the conformal coating compositions, standard mount thick films resistors, containing silver contacts within the resistor body, were soldered on to a printed circuit board test card with gold tabs allowing for easy resistance probing. The conformal coating compositions with and without the high surface area filler were then applied over the thick film resistors and allowed to cure at room temperature for 24 hours prior to being subjected to the flowers of sulfur (FoS) environment. Triplicate samples from each conformal coating were prepared.

Once cured, the test cards were placed into a desiccator that contained elemental sulfur (250 g). The desiccator was then placed into an over at 105° C. The resistances of the thick film resistors were measured every 48 hours. This was accomplished by removed the test cards from the oven and allowing to cool to room temperature, then each resistor location was probed with a Fluke® multimeter.

Our results demonstrate that the incorporation of a high surface area filler can extend the time to corrosion related failure of silver containing thick film resistors. In Table 1, it can be observed that as the loading of the high surface area filler increases, the time to corrosion failure of silver containing thick film resistors in a sulfur environment also increases. A resistor coated with a conformal coating not containing the high surface area filler failed within 48 hours. All resistors coated with the conformal coating compositions containing the high surface area filler did not fail for nearly 200 hours with the highest loading of the high surface area filler not failing for over 280 hours. Based upon developed acceleration standards from the modified FoS test, it is expected that the conformal coating compositions containing high surface area filler will extend resistor life several years.

What is claimed is:

1. A high surface area filler, comprising:
an amorphous silicon dioxide powder; and
a phosphine compound bonded to the amorphous silicon dioxide powder.

2. The high surface area filler as recited in claim 1, wherein the amorphous silicon dioxide powder has a surface area in a range from about 50 sq. m/g to 600 sq. m/g.

3. The high surface area filler as recited in claim 1, wherein the amorphous silicon dioxide powder has a surface area in a range from about 150 sq. m/g to 250 sq. m/g.

4. The high surface area filler as recited in claim 1, wherein the phosphine compound is selected from a group consisting of alkyl phosphines and aryl phosphines; and combinations thereof.

5. The high surface area filler as recited in claim 1, wherein the phosphine compound is selected from a group consisting of substituted or unsubstituted tributyl phosphine and substituted or unsubstituted triphenyl phosphines; and combinations thereof.

6. A conformal coating composition, comprising:
a conformal coating; and
a high surface area filler, wherein the high surface area filler comprises an amorphous silicon dioxide powder and a phosphine compound bonded to the amorphous silicon dioxide powder.

7. The conformal coating composition of claim 6, wherein the high surface area filler is in a range from about 0.1 to about 55 percent by weight based on the total weight of the conformal coating and the high surface area filler in the conformal coating composition.

8. The conformal coating composition of claim 6, wherein the high surface area filler is in a range from about 10 to about 40 percent by weight based on the total weight of the conformal coating and the high surface area filler in the conformal coating composition.

9. The conformal coating composition of claim 6, wherein the high surface area filler is in a range from about 15 to about 30 percent by weight based on the total weight of the conformal coating and the high surface area filler in the conformal coating composition.

10. The conformal coating composition as recited in claim 6, wherein the phosphine compound is selected from a group consisting of alkyl phosphines and aryl phosphines; and combinations thereof.

11. The conformal coating composition as recited in claim 6, wherein the phosphine compound is selected from a group consisting of substituted or unsubstituted tributyl phosphine and substituted or unsubstituted triphenyl phosphines; and combinations thereof.

12. The conformal coating composition as recited in claim 6, wherein the amorphous silicon dioxide powder has a surface area in a range from about 50 sq. m/g to 600 sq. m/g.

13. The conformal coating composition as recited in claim 6, wherein the amorphous silicon dioxide powder has a surface area in a range from about 150 sq. m/g to 250 sq. m/g.

14. An apparatus, comprising:
a substrate;
an electronic component mounted on the substrate;
metal conductors electrically connecting the electronic component; and
a conformal coating composition overlying the metal conductors, wherein the conformal coating composition comprises a conformal coating, and a high surface area filler, wherein the high surface area filler comprises an amorphous silicon dioxide powder and a phosphine compound bonded to the amorphous silicon dioxide powder.

15. The apparatus as recited in claim 14, wherein the electronic component is a gate resistor of a resistor network array, and wherein the metal conductors comprise an inner silver layer of the gate resistor.

16. The apparatus as recited in claim 14, wherein the phosphine compound is selected from a group consisting of alkyl phosphines and aryl phosphines; and combinations thereof.

17. The apparatus as recited in claim 14, wherein the phosphine compound is selected from a group consisting of substituted or unsubstituted butyl phosphines and substituted or unsubstituted phenyl phosphines; and combinations thereof.

18. The apparatus as recited in claim 14, wherein the conformal coating composition contains the high surface area filler in a range from about 0.1 to about 55 percent by weight based on the total weight of the conformal coating and the high surface area filler in the conformal coating composition.

19. The apparatus as recited in claim 14, wherein the conformal coating composition contains the high surface area filler is in a range from about 10 to about 40 percent by weight based on the total weight of the conformal coating and the high surface area filler in the conformal coating composition.

20. The apparatus as recited in claim 14, wherein the conformal coating composition contains the high surface area filler is in a range from about 15 to about 30 percent by weight based on the total weight of the conformal coating and the high surface area filler in the conformal coating composition.
